(19) United States
(12) Patent Application Publication
(10) Pub. No.: US 2013/0017315 A1
(43) Pub. Date: Jan. 17, 2013

(54) METHODS AND APPARATUS FOR CONTROLLING POWER DISTRIBUTION IN SUBSTRATE PROCESSING SYSTEMS

(71) Applicants: CANFENG LAI, Fremont, CA (US); DAVID EUGENE ABERLE, Milpitas, CA (US); MICHAEL P. CAMP, San Ramon, CA (US); HENRY BARANDICA, San Jose, CA (US); MARTIN A. HILKENE, Gilroy, CA (US); MATTHEW D. SCOTNEY-CASTLE, Morgan Hill, CA (US); JEFFREY TOBIN, Mountain View, CA (US); DOUGLAS H. BURNS, Saratoga, CA (US); LARA HAWRYLCHAK, Gilroy, CA (US)

(72) Inventors: CANFENG LAI, Fremont, CA (US); DAVID EUGENE ABERLE, Milpitas, CA (US); MICHAEL P. CAMP, San Ramon, CA (US); HENRY BARANDICA, San Jose, CA (US); MARTIN A. HILKENE, Gilroy, CA (US); MATTHEW D. SCOTNEY-CASTLE, Morgan Hill, CA (US); JEFFREY TOBIN, Mountain View, CA (US); DOUGLAS H. BURNS, Saratoga, CA (US); LARA HAWRYLCHAK, Gilroy, CA (US); PETER I. PORSHNEV, Poway, CA (US)

(73) Assignee: APPLIED MATERIALS, INC., Santa Clara, CA (US)

(21) Appl. No.: 13/183,921

(22) Filed: Jul. 15, 2011

(51) Int. Cl. C23C 16/505; C23C 16/52; H05H 1/46

(52) U.S. Cl. 427/8; 204/298.34; 204/192.33; 204/298.32; 118/723 I; 118/697

(57) ABSTRACT

Methods and apparatus for controlling power distribution in a substrate processing system are provided. In some embodiments, a substrate processing system including a process chamber having a substrate support and a processing region disposed above the substrate support; a first conduit disposed above the processing region to provide a portion of a first toroidal path that extends through the first conduit and across the processing region; a second conduit disposed above the processing region to provide a portion of a second toroidal path that extends through the second conduit and across the processing region; an RF generator coupled to the first and second conduits to provide RF energy having a first frequency to each of the first and second conduits; an impedance matching network disposed between the RF generator and the first and second conduits; and a power divider to control the amount of RF energy provided to the first and second conduits from the RF generator.

### FIELD

Embodiments of the present invention generally relate to substrate processing systems, and methods of controlling power distribution therein.

### BACKGROUND

Toroidal source plasma reactors may be utilized to generate high density plasmas for etching or doping applications. In some conventional designs, two independent toroidal plasma sources may be used, for example, for plasma doping processes. Such designs utilize two frequency tuning radio frequency (RF) generators, one for each toroidal path of the reactor. Each RF generator is used without any impedance matching network. However, although such designs do provide certain benefits, for example, offering a large grounded surface area for high bias to develop on a substrate being processed, the inventors have discovered certain drawbacks of these designs.

Thus, the inventors have provided improved methods and apparatus for controlling power distribution in toroidal source plasma reactors.

### SUMMARY

Methods and apparatus for controlling power distribution in a substrate processing system are provided herein. In some embodiments, an apparatus includes a substrate processing system including a process chamber having a substrate support disposed in the process chamber and a processing region disposed above the substrate support; a first conduit disposed above the processing region to provide a portion of a first toroidal path that extends through the first conduit and across the processing region; a second conduit disposed above the processing region to provide a portion of a second toroidal path that extends through the second conduit and across the processing region; an RF generator coupled to the first and second conduits to provide RF energy having a first frequency to each of the first and second conduits; an impedance matching network disposed between the RF generator and the first and second conduits; and a power divider to control the amount of RF energy provided to the first and second conduits from the RF generator.

In some embodiments, a method of controlling power distribution in a substrate processing system having an RF energy source coupled to a pair of electrodes via a power divider that controls the amount of RF current respectively provided to each electrode includes adjusting a position of a variable element of the power divider based on a pre-determined relationship between the position of the variable element and a current ratio to divide the magnitude of a current provided by an RF energy source between a first and a second toroidal path; measuring a first magnitude of a first current provided to the first toroidal path and a first magnitude of a second current provided to the second toroidal path; and adjusting the position of the variable element from a first position to a second position if the difference between a first value of the current ratio and a desired value of the current ratio is not within a desired tolerance level, wherein the first value of the current ratio is determined from the measured first magnitudes of the first and second currents.

In some embodiments, a computer readable medium is provided having instruction stored thereon that, when executed by a processor, cause a process chamber to perform a method of controlling power distribution in a substrate processing system having an RF energy source coupled to a pair of electrodes via a power divider that controls the amount of RF current respectively provided to each electrode. In some embodiments, the method may be any of the methods described herein.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic view of a plasma immersion ion implantation process chamber in accordance with some embodiments of the present invention.

FIG. 2 depicts a top down view of the plasma immersion ion implantation process chamber of FIG. 1 in accordance with some embodiments of the present invention.

FIG. 3 depicts a flow chart for a method of controlling power distribution in a substrate processing system in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods and apparatus for controlling power distribution in a substrate processing system are disclosed herein. The inventive methods and apparatus may advantageously reduce particle and/or metal contamination from plasma sources by improving power delivery to a plurality of conduits in a toroidal source plasma reactor. For example, embodiments of the inventive apparatus may reduce instabilities a plasma generated in the reactor by better matching power delivery to each of the plurality of conduits. Embodiments of the present inventive methods may advantageously allow an operator to input a desired value for a current ratio used to distribute power between each of the plurality of conduits based on a pre-determined relationship between a position of a variable element in the power divider and the current ratio.

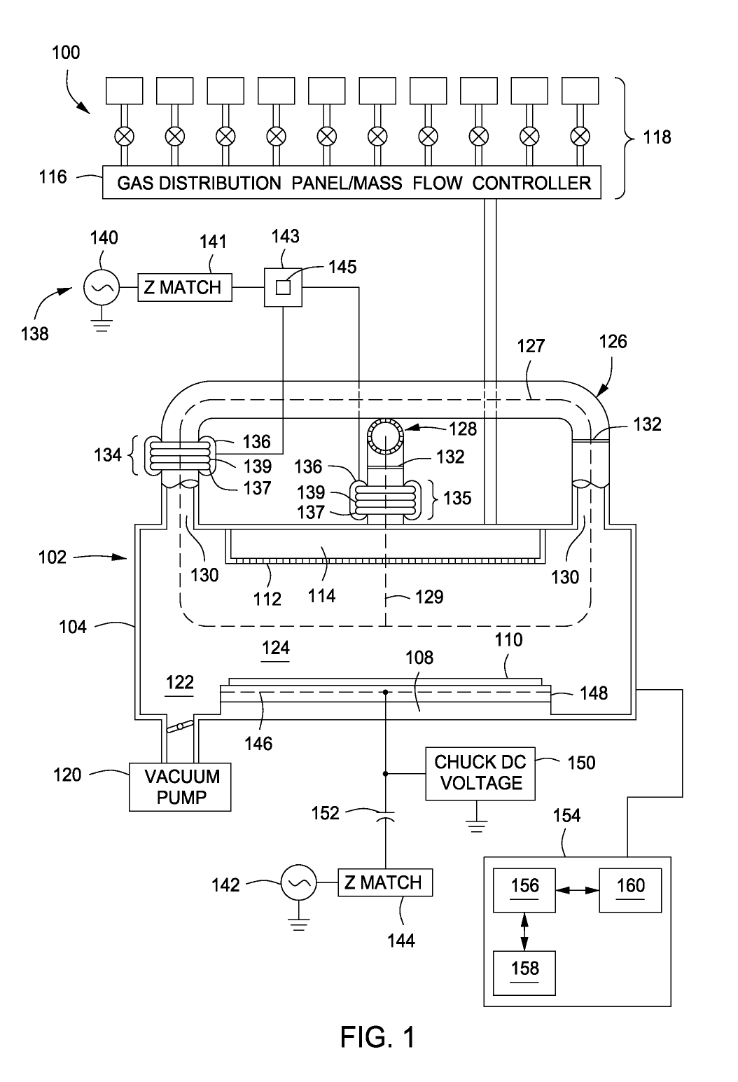

FIG. 1 illustrates one embodiment of toroidal source plasma ion immersion implantation reactor such as, but not limited to, the CONFORMA™ reactor commercially available from Applied Materials, Inc., of Santa Clara, Calif. Such a suitable reactor and its method of operation are set forth in U.S. Pat. No. 7,166,524, assigned to the assignee of the present invention.

Referring to FIG. 1, a toroidal source plasma immersion ion implantation reactor 100 (e.g., a substrate processing system) may include a cylindrical vacuum chamber 102 (e.g., a process chamber) defined by a cylindrical side wall 104 and a disk-shaped ceiling 106. A substrate support 108 at the floor of the chamber 102 supports a substrate 110 to be processed. A gas distribution plate or showerhead 112 on the ceiling 106 receives process gas in its gas manifold 114 from a gas distribution panel 116 whose gas output can be any one of or mixtures of gases from one or more individual gas supplies 118. A vacuum pump 120 is coupled to a pumping annulus 122 defined between the substrate support 108 and the sidewall 104. A processing region 124 may be defined above the substrate support 108 and between the substrate 110 and the gas distribution plate 112.

A pair of external reentrant conduits, a first conduit 126 and a second conduit 128, establish reentrant toroidal paths for plasma currents passing through the processing region, the toroidal paths intersecting in the processing region 124. For example, the first conduit 126 may be disposed above the processing region 124 to provide a portion of a first toroidal path 127 that extends through the first conduit 126 and across the processing region 124. Similarly, the second conduit 126 (shown in cross sectional view in FIG. 1) may be disposed above the processing region 124 to provide a portion of a second toroidal 129 path that extends through the second conduit 126 and across the processing region 124.

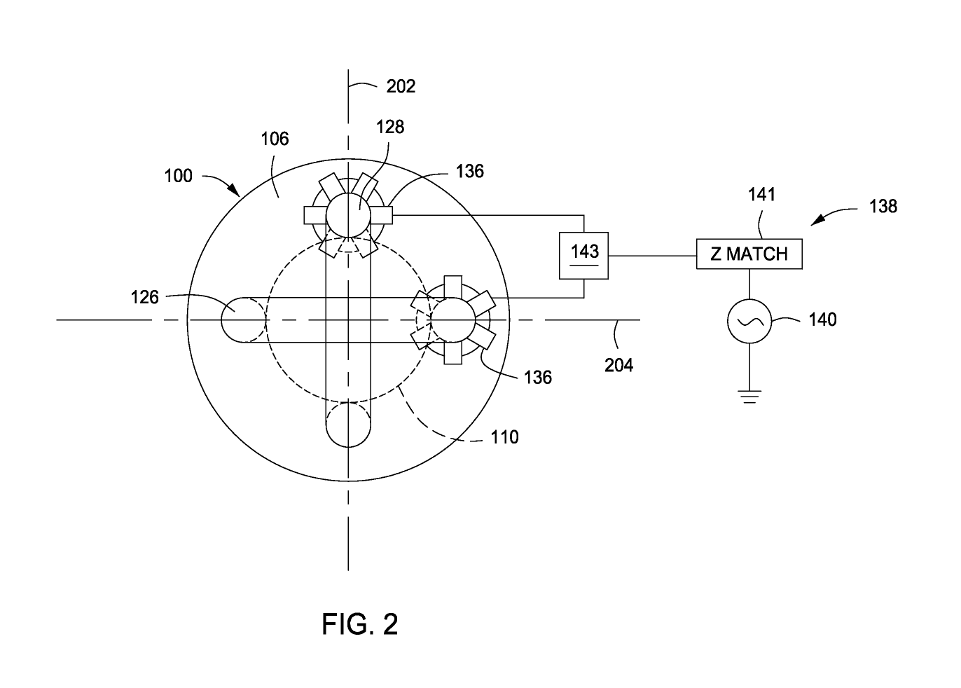

In some embodiments, as illustrated in a top down view in FIG. 2, the first conduit 126 may provide a first axial flow path that is perpendicular to a second axial flow path provided by the second conduit 128. Accordingly, a first axis 202 of the first toroidal flow path 127 may be perpendicular to a second axis 204 of the second toroidal flow path 129. However, the first and second axial flow paths need not be perpendicular and other relative angles of the first axis 202 and the second axis 204 may be provided.

Returning to FIG. 1, each of the conduits 126, 128 has a pair of ends 130 (illustrated in FIG. 1 for the first conduit 126) coupled to opposite sides of the chamber. Each conduit 126, 128 is a hollow conductive tube. Each conduit 126, 128 has a D.C. insulation ring 132 preventing the formation of a closed loop conductive path between the two ends of the conduit. A portion of each conduit 126, 128, may be surrounded by an applicator to couple current provided by the RF energy source to respective ones of the conduits 126, 128. For example, a first applicator 134 may couple a first portion of the magnitude of the current provided by the RF energy source to the first conduit. Similarly, a second applicator 135 may couple a second portion of the magnitude of the current provided by the RF energy source to the second conduit. In some embodiments, the applicators may be a core applicator comprising ferrite cores and RF coils. For example, each of the first or second applicators 134, 135 may include one or more first metal-containing rings 137 disposed about a circumference of the first conduit, one or more second metal-containing rings 139 disposed about the circumference of the first conduit, and one or more conductive coils 136 wrapped around the one or more first and second metal-containing rings 137,139 in a direction perpendicular to the circumference of a respective conduit. The one or more first metal-containing rings 137 may comprise copper (Cu). The one or more second metal-containing rings may comprise iron (Fe). The one or more second metal-containing rings 139 may be disposed between the one or more first metal-containing rings 137. Other applicator configurations may be provided to couple the RF energy to the respective conduits 126, 128.

Each of the one or more conductive coils 136 is coupled to an RF energy source 138. The RF energy source 138 provides RF energy to each of the first and second conduits 126, 128 and further controls a power distribution of the RF energy provided to each of the first and second conduits 126, 128. For example, the RF energy source 138 may include an RF generator 140, an impedance matching network 141 disposed between the RF generator 140 and the first and second conduits 126, 128, and a power divider 143 disposed between the impedance matching network 141 and the first and second conduits 126, 128 to control the amount of power provided to the first and second conduits 126, 128.

In some embodiments, the RF generator 140 may provide between about 100 to about 3000 watts of RF energy at a frequency of about 400 kHz to about 14 MHz to the first and second conduits 126, 128. The RF energy coupled from the RF energy source 138 produces plasma ion currents in the first and second toroidal paths 127, 129 extending through the respective first and second conduits 126, 128 and through the processing region 124. These ion currents oscillate at the frequency provided by the RF generator 140. In some embodiments, bias power may be applied to the substrate support 108 by a bias power generator 142 through an impedance matching network 144.

The impedance matching network 141 facilitates a large tuning space that covers the special impedance of the toroidal plasmas. The large tuning range ensures maximum power coupling with minimum reflected power, thereby advantageously providing a stable plasma that may reduce particle and metal contamination from the plasma sources as compared to conventional toroidal reactors. Moreover, the improved power coupling provided by embodiments of the present invention may also facilitate widening the process window or operating range of the apparatus as compared to conventional toroidal reactors.

The power divider 143 may be coupled between the impedance matching network 141 and the first and second conduits 126, 128. Alternatively, the power divider 143 may be a part of the impedance matching network 141, in which case the impedance matching network 141 will have two outputs—one corresponding to each conduit 126, 128. The power divider 143 may include a variable element 145 to divide a magnitude of current provided by the RF energy source 138 between the first and second conduits 126, 128. For example, in some embodiments, the variable element 145 may be an adjustable capacitor.

The power divider 143 (or the impedance matching network 141, when the power divider 143 is a part of the impedance matching network) is designed to provide a configurable current ratio between two outputs to the respective toroidal plasma. In some embodiments, the power divider 143 (or the impedance matching network 141, when the power divider 143 is a part of the impedance matching network) is designed to tune to the configurable current ratio. For example, a current sensor (not shown) may be provided for each output that measures the current. The values sensed by the sensors are provided to a controller, such as a controller in the impedance matching network 141, the controller 154 discussed below, or some other similar controller. The controller calculates the actual current ratio and compares the actual ratio to the desired ratio (for example, a setpoint from the recipe on the tool). The controller may then adjust the power divider 143 to match the measurement (the actual current ratio) to the setpoint (the desired current ratio). In some embodiments, the tuning may be continuously performed to make sure that both the impedance tuning requirement (minimum reflected power) and the current ratio tuning requirement are met at the same time. The current ratio may be predetermined, for example, by a tool operator while developing a particular process recipe. The range of the current ratio may be sufficiently large to allow tuning of the uniformity of the plasma above a substrate disposed on the substrate support (e.g., downstream of the two toroidal plasmas in the respective first and second conduits). In some embodiments, a power meter (not shown), such as Z'Scan®, commercially available from Advanced Energy, can be incorporated to measure other RF parameters, such as voltage, phase angle, and the like, thereby facilitating calculation of the net power applied.

Plasma formation and subsequent processes, such as etching, doping, or layer formation may be performed by introducing the process gases into the chamber 124 through the gas distribution plate 112 and applying sufficient source power from the RF energy source 138 to the first and second conduits 126, 128 to create toroidal plasma currents in the conduits and in the processing region 124. The plasma flux proximate the substrate surface is determined by the substrate bias voltage applied by the RF bias power generator 142. The plasma rate or flux (number of ions sampling the substrate surface per square cm per second) is determined by the plasma density, which is controlled by the level of RF energy applied by the RF energy source 138. The cumulative ion dose (ions/square cm) at the substrate 110 is determined by both the flux and the total time over which the flux is maintained. For example, by adjusting the variable element 145, the plasma density along each of the first and second toroidal paths 127, 129 may be changed.

If the substrate support 108 is an electrostatic chuck, then a buried electrode 146 is provided within an insulating plate 148 of the substrate support, and the buried electrode 146 is coupled to the bias power generator 142 through the impedance match circuit 144. A DC chucking supply 150 may also be coupled to the buried electrode 146, or to another electrode disposed in the substrate support 108 to provide a DC chucking voltage for retaining a substrate on the substrate support 108.

In operation, a process, such as etching, doping, or layer formation on the substrate 110 can be achieved by placing the substrate 110 on the substrate support 108, introducing one or more process gases into the chamber 102 and striking a plasma from the process gases. The substrate bias voltage delivered by the RF bias power generator 142 can be adjusted to control the flux of ions to the substrate surface.

A controller 154 comprises a central processing unit (CPU) 156, a memory 158, and support circuits 160 for the CPU 156 and facilitates control of the components of the chamber 102 and, as such, of the etch process, as discussed below in further detail. To facilitate control of the process chamber 102, for example as described below, the controller 154 may be one of any form of general-purpose computer processor that can be used in an industrial setting for controlling various chambers and sub-processors. The memory 158, or computer-readable medium, of the CPU 156 may be one or more of readily available memory such as random access memory (RAM), read only memory (ROM), floppy disk, hard disk, or any other form of digital storage, local or remote. The support circuits 160 are coupled to the CPU 156 for supporting the processor in a conventional manner. These circuits include cache, power supplies, clock circuits, input/output circuitry and subsystems, and the like. The inventive methods described herein may be stored in the memory 158 as a software routine. The software routine may also be stored and/or executed by a second CPU (not shown) that is remotely located from the hardware being controlled by the CPU 156.

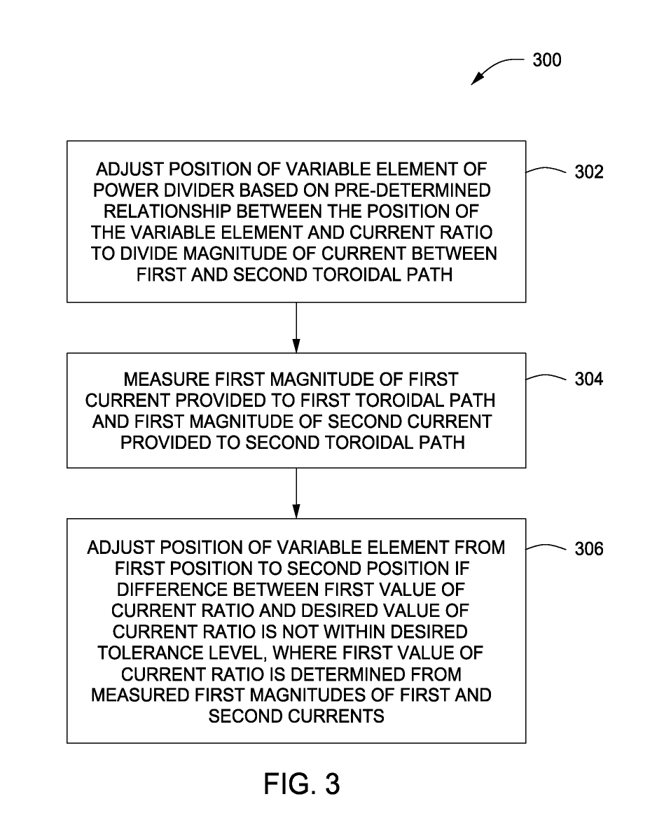

FIG. 3 depicts a flow chart of a method 300 for controlling power distribution in a process chamber in accordance with some embodiments of the invention. The method 300 may be performed in a substrate processing system having an RF energy source coupled to a pair of electrodes via a power divider that controls the amount of RF current respectively provided to each electrode, such as the reactor 100 illustrated in FIG. 1-2 and discussed above. The method 300 is described below in accordance with the reactor 100.

The method begins at 302 by adjusting a position of the variable element 145 of the power divider 143 based on a pre-determined relationship between the position of the variable element 145 and a current ratio to divide the magnitude of a current provided by the RF energy source 138 between the first and the second toroidal path 127, 129. For example, an operator may provide a desired value of the current ratio as an input and the position of the variable element 145 may be automatically adjusted to provide the desired value of the current ratio based on the pre-determined relationship. For example, the pre-determined relationship may be determined from a calibration procedure or the like, preformed at startup of the reactor 100 or at any desired time, such as when the reactor 100 is serviced or the like. In some embodiments, use of predetermined tuning element values may facilitate speeding up the tuning process. The number of different presets can be predetermined for various applications which may have different operational parameters, such as chamber pressure, gas flow, gas compositions, power levels, and the like.

At 304, a first magnitude of a first current provided to the first toroidal path 127 and a first magnitude of a second current provided to the second toroidal path 129 is measured. The magnitudes of the first and second currents may be obtained as discussed above. If the difference between a first value of the current ratio and the desired value of the current ratio is within a desired tolerance level, then the reactor 100 may be suitable for operation at the desired value of the current ratio. The first value of the current ratio may be determined from the measured first magnitudes of the first and second currents. However, if the difference between the first value and the desired value is not with the desired tolerance level, the method may proceed to 306.

At 306, the position of the variable element 145 may be adjusted from a first position to a second position if the difference between the first value of the current ratio and the desired value of the current ratio is not within the desired tolerance level. For example, a control method for adjusting the variable element may be any suitable control method, such as proportional-integral-derivative (PID) control or the like. For example, after an adjustment is made to the second position, a second magnitude of the first current and a second magnitude of the second current may be measured when the variable element 145 is set in the second position. If the difference between a second value of the current ratio—determined from the measured second magnitudes of the first and second currents—and the desired current ratio is not within the desired tolerance level, the position of the variable element may be adjusted from the second position to a third position, and further to as many successive positions as necessary to reach the desired value within the desired tolerance level. In some embodiments, the desired value of the current ratio is about 1 (e.g., the apparatus may be controlled to provide the same RF current to each conduit).

Thus, methods and apparatus for controlling power distribution in a substrate processing system are disclosed herein. Embodiments of the inventive methods and apparatus may advantageously reduce particle and/or metal contamination from plasma sources by improving power delivery to a plurality of conduits in a toroidal source plasma reactor. For example, embodiments of the inventive apparatus may reduce instabilities a plasma generated in the reactor by better matching power delivery to each of the plurality of conduits. Embodiments of the inventive methods may advantageously allow an operator to input a desired value for a current ratio used to distribute power between each of the plurality of conduits based on a pre-determined relationship between a position of a variable element in the power divider and the current ratio.

While the foregoing is directed to embodiments of the present invention, other and further embodiments of the invention may be devised without departing from the basic scope thereof. For example, although discussed above as used in connection with a toroidal plasma chamber, any RF delivery for two separate inductively coupled plasma sources can potentially benefit from embodiments of the methods and apparatus described above.

1-7. (canceled)

8. A method of controlling power distribution in a substrate processing system having first and second conduits each respectively defining part of a first toroidal path and a second toroidal path, wherein each conduit includes an electrode coupled to an RF energy source via a power divider and an impedance matching network, wherein the power divider controls the amount of RF current respectively provided to each electrode, the method comprising:
adjusting a position of a variable element of the power divider based on a pre-determined relationship between the position of the variable element and a current ratio of RF current respectively provided to the first and second conduit in order to divide the magnitude of a current provided by an RF energy source between the first and the second toroidal path;
measuring a first magnitude of a first current provided to the first toroidal path and a first magnitude of a second current provided to the second toroidal path; and
adjusting the position of the variable element from a first position to a second position if the difference between a first value of the current ratio and a desired value of the current ratio is not within a desired tolerance level, wherein the first value of the current ratio is determined from the measured first magnitudes of the first and second currents.

9. The method of claim 8, wherein the difference between the actual current ratio and the desired current ratio is not within the desired tolerance level, and further comprising:
measuring a second magnitude of the first current and a second magnitude of the second current when the variable element is set in the second position; and
adjusting the position of the variable element from the second position to a third position if the difference between a second value of the current ratio and the desired value of the current ratio is not within the desired tolerance level, wherein the second value of the current ratio is determined from the measured second magnitudes of the first and second currents.

10. The method of claim 8, wherein the variable element is an adjustable capacitor.

11. The method of claim 8, wherein a first axis of the first toroidal path is oriented perpendicular to a second axis of the second toroidal path.

12. The method of claim 8, wherein the desired value of the current ratio is about 1.

13. A computer readable medium having instructions stored thereon that, when executed by a processor, cause a process chamber to perform a method of controlling power distribution in a substrate processing system having first and second conduits each respectively defining part of a first toroidal path and a second toroidal path, wherein each conduit includes an electrode coupled to an RF energy source via a power divider and an impedance matching network, wherein the power divider controls the amount of RF current respectively provided to each electrode, the method comprising:
adjusting a position of a variable element of the power divider based on a pre-determined relationship between the position of the variable element and a current ratio of RF current respectively provided to the first and second conduit in order to divide the magnitude of a current provided by an RF energy source between the first and the second toroidal path;
measuring a first magnitude of a first current provided to the first toroidal path and a first magnitude of a second current provided to the second toroidal path; and
adjusting the position of the variable element from a first position to a second position if the difference between a first value of the current ratio and a desired value of the current ratio is not within a desired tolerance level, wherein the first value of the current ratio is determined from the measured first magnitudes of the first and second currents.

14. The computer readable medium of claim 13, wherein the difference between the actual current ratio and the desired current ratio is not within the desired tolerance level, and further comprising:
measuring a second magnitude of the first current and a second magnitude of the second current when the variable element is set in the second position; and
adjusting the position of the variable element from the second position to a third position if the difference between a second value of the current ratio and the desired value of the current ratio is not within the desired tolerance level, wherein the second value of the current ratio is determined from the measured second magnitudes of the first and second currents.

15. The computer readable medium of claim 13, wherein the variable element is an adjustable capacitor.

16. The computer readable medium of claim 13, wherein a first axis of the first toroidal path is oriented perpendicular to a second axis of the second toroidal path.

17. The computer readable medium of claim 13, wherein the desired value of the current ratio is about 1.

18. The method of claim 8, wherein the power divider is part of an impedance matching network comprising a first output coupled to the first toroidal path and a second output coupled to the second toroidal path, wherein the power divider controls the amount of RF energy provided through the first and second outputs of the impedance matching network.

19. The method of claim 18, further comprising:
controlling the position of the power divider using a controller coupled thereto in order to control the amount of RF energy provided to the first and second toroidal paths from the RF energy source.

20. The method of claim 19, further comprising:
measuring the current at each of the first and second outputs using a current sensor; and
providing the value of the current for each of the first and second outputs to the controller.

21. The method of claim 8, wherein the RF energy source provides a range of about 100 watts to 3000 watts of energy at a frequency of about 400 kHz to about 14 MHz to the first toroidal path and second toroidal path.

22. The computer readable medium of claim 13, wherein the power divider is part of a impedance matching network comprising a first output coupled to the first toroidal path and a second output coupled to the second toroidal path, wherein the power divider controls the amount of RF energy provided through the first and second outputs of the impedance matching network.

23. The computer readable medium of claim 13, wherein the RF energy source provides a range of about 100 watts to 3000 watts of energy at a frequency of about 400 kHz to about 14 MHz to the first toroidal path and second toroidal path.

24. A method of controlling power distribution in a substrate processing system having first and second conduits each respectively defining part of a first toroidal path and a second toroidal path, wherein each conduit includes an electrode coupled to an RF energy source via a power divider and an impedance matching network, wherein the power divider controls the amount of RF current respectively provided to each electrode, the method comprising:
adjusting a position of a variable element of the power divider based on a pre-determined relationship between the position of the variable element and a current ratio in order to divide the magnitude of a current provided by an RF energy source between a first toroidal path and a second toroidal path, wherein the current ratio is the ratio of power distributed to the first and second conduit by the RF energy source;
measuring a first magnitude of a first current provided to the first toroidal path and a first magnitude of a second current provided to the second toroidal path; and
adjusting the position of the variable element from a first position to a second position if the difference between a first value of the current ratio and a desired value of the current ratio is not within a desired tolerance level, wherein the first value of the current ratio is determined from the measured first magnitudes of the first and second currents.

25. The method of claim 24, further comprising:
applying a bias power to a substrate support by a bias power generator through the impedance matching network.
